(19) United States
(12) Patent Application Publication
(10) Pub. No.: US 2011/0198219 A1
(43) Pub. Date: Aug. 18, 2011

(54) MAGNETRON SPUTTERING DEVICE

(76) Inventors: Tadahiro Ohmi, Miyagi (JP); Tetsuya Goto, Miyagi (JP)

(21) Appl. No.: 13/125,472

(22) PCT Filed: Oct. 9, 2009
(86) PCT No.: PCT/JP2009/067601

§ 371 Date: Apr. 21, 2011

(30) Foreign Application Priority Data
Oct. 22, 2008 (JP) 2008-271810

(51) Int. Cl. C23C 14/35

(52) U.S. Cl. 204/298.08; 204/298.12

(57) ABSTRACT

An object of the present invention is to improve a sputtering efficiency and a production efficiency in a magnetron sputtering method using a rectangular target. A magnetron sputtering apparatus 10 according to the present invention is a vertical-passing-type sputtering apparatus for performing a sputtering deposition process while moving (passing) substrate P_{L} and P_{R} in a state in which the substrates are vertically raised. The magnetron sputtering apparatus 10 is formed as a sputtering apparatus capable of simultaneously processing two substrates with a single or common magnetic field generation mechanism 42 and targets 12L and 12R of bilateral symmetry (symmetry between the upper target and the lower target in the drawing).

### TECHNICAL FIELD

The present invention relates to a magnetron sputtering method using a magnetron discharge in a sputtering process, and more particularly to a magnetron sputtering apparatus using a rectangular target.

### BACKGROUND ART

For manufacturing a semiconductor device or a flat panel display (FPD), a process of forming a predetermined thin film on a substrate to be processed (a semiconductor wafer, a glass substrate, or the like) and a process of patterning the thin film by lithography and etching the thin film are repeated many times. A sputtering method is a thin film formation technique using a physical vapor deposition (PVD) for sputtering a target (thin film base material) by ion bombardment to deposit atoms of the target material on a substrate and is widely used in a semiconductor fabrication process. Among others, a magnetron sputtering method is the most practical and is thus a predominant sputtering method.

In a magnetron sputtering method, a magnet is disposed at a rear side of a target near a cathode in a parallel-plate bipolar sputtering apparatus, and a magnetic field is formed so as to leak into a front side of the target. In this case, the bipolar magnet (with an N-pole and an S-pole) is arranged such that, while the leakage magnetic field has a component parallel to a surface of the target, the parallel component of the magnetic field is distributed in the form of a loop in a direction that is parallel to the surface of the target and is perpendicular to the line of magnetic force. With such a configuration, secondary electrons sputtered from the surface of the target by injection of ions receive a Lorentz force so as to move along the loop on a closed path of a cycloid. The secondary electrons are bound near the surface of the target so as to promote generation of a plasma or ionization of a sputtering gas with a magnetron discharge. According to this technique, a high current density can be obtained even under a low pressure, and a sputtering deposition can be performed at a low temperature and a high speed.

In a magnetron sputtering method, a target in the form of a circular plate or a rectangular plate is used in a case of typical parallel-plate bipolar sputtering. In this case, if a leakage magnetic field being formed remains on a surface of the target, the surface of the target is locally eroded only at a portion that faces the aforementioned loop, i.e., the plasma ring. Thus, the effective utilization ratio of the target is low, and the result is undesirable in view of the uniformity of the sputtering deposition. Therefore, a mechanism for moving (rotating, translating, swinging, or the like) the magnet on the rear side of the target in a proper manner is provided so that the plasma ring traces the surface of the target in a range as wide as possible.

Patent Document 1 discloses a magnetron sputtering apparatus that uses a target in the form of a relatively elongated rectangular plate and moves an eroded area of a surface of the target in a longitudinal direction of the target to improve the utilization ratio and the ablation uniformity of the target and the uniformity of the sputtering deposition.

In this magnetron sputtering apparatus, N-pole magnetic shells and S-pole magnetic shells are spirally attached to a circumference of a columnar rotation axis extending in parallel to the longitudinal direction of the target behind the target in such a manner that they are spaced at constant intervals in an axial direction, thereby forming a rotation magnet group. Furthermore, a fixing peripheral magnetic shell that has substantially the same outline dimension (width and length) as the target and is in the form of a rectangular frame is provided so as to surround the rotation magnet group at a location close to a rear face of the target. According to such a magnetic field generation mechanism, a large number of plasma rings that roughly have an elliptic shape with a minor axis substantially equal to the pitch of the spiral and a major axis substantially equal to the width of the target can be formed on a front face of the target and arranged in the axial direction. Those plasma rings are moved in the longitudinal direction of the target by rotating the rotation magnet group integrally with the columnar rotation axis.

### PRIOR ART DOCUMENTS

### Patent Documents

Patent Document 1: International Publication WO2007/043476

### SUMMARY OF THE INVENTION

### Problem(s) to be Solved by the Invention

In the magnetron sputtering apparatus disclosed in Patent Document 1, from the viewpoint of the structure of the magnetic coupling between the rotation magnet group attached to the columnar rotation axis and the fixing peripheral magnetic shell disposed around the rotation magnet group, the size of the rectangular target theoretically has no specific limitation in the axial direction but has a limitation of about 120 mm to about 130 mm in the width direction. Therefore, a method of resting both of the target and the substrate cannot be used in order to form a sputtering film, with use of one rectangular target, on the entire surface of a semiconductor wafer having a large diameter (e.g., a diameter of 300 mm) as well as a substrate for a general FPD. Thus, there is used a method of moving the target and the substrate relative to each other in one direction so as to scan from one end to another end of the substrate for a sputtering deposition. Generally, while the target is fixed, the substrate is moved across a sputtering space in front of the target.

Use of such a scanning method permits continuous operation of the apparatus and can maximize the rate of operation of the apparatus. However, when a magnetron sputtering apparatus is to be incorporated into an in-line system including various pressure-reducible devices in a FPD fabrication line or a semiconductor fabrication line, the production efficiency per apparatus is an important consideration for adoption of the apparatus as well as the rate of operation. Specifically, if the production efficiency is low, the number of apparatuses increases in order to compensate the low production efficiency. As a result, not only the cost of the apparatuses but also the footprint of the apparatuses disadvantageously increases. Thus, the performance of the apparatus is negatively evaluated.

The present invention has been made in view of the aforementioned circumstances and problems of the prior art. It is, therefore, an object of the present invention to provide a magnetron sputtering apparatus that achieves dramatic improvements of a sputtering efficiency and a production efficiency in a magnetron sputtering method.

### Means to Solve the Problem(s)

In order to achieve the above-mentioned object, a magnetron sputtering apparatus according to a first aspect of this invention comprises a magnetic field generation mechanism including a rotation magnet group of a plurality of plate magnets attached to an outer circumferential surface of a columnar rotation axis in a predetermined arrangement pattern, the magnetic field generation mechanism being operable to drive rotation of the rotation magnet group integrally with the columnar rotation axis, a plurality of target holding mechanisms each extending in parallel to the columnar rotation axis such that a rear face of each of the target holding mechanisms faces the rotation magnet group, the plurality of target holding mechanisms being provided around the rotation magnet group so that the target holding mechanisms do not overlap in a radial direction of the columnar rotation axis, a plurality of processing chambers that receive substrates to be processed in a state in which the substrates are opposed to front faces of the plurality of target holding mechanisms so that the substrates can individually be transported into and from the plurality of processing chambers, the plurality of processing chambers being capable of decompression, a gas supply mechanism for supplying a sputtering gas to the processing chambers; and a power supply mechanism for supplying electric power for electric discharge to each of the targets to generate plasma of the sputtering gas in each of the processing chambers. In this case, a magnetic field for confining the plasma of the sputtering gas is formed by the magnetic field generation mechanism so that a sputtering process can be performed in the plurality of processing chambers.

With the above configuration in the first aspect of the magnetron sputtering apparatus, thin films of the same material or different materials can simultaneously be formed on a plurality of substrates in a plurality of processing chambers with a plurality of targets by using a single or common magnetic field generation mechanism. Thus, a throughput or a production efficiency equivalent to those of two apparatuses can be achieved with a single compact apparatus. Furthermore, the magnetic field generation mechanism, which exerts the largest influence on the magnetron discharge characteristics, is used in common to a plurality of processing chambers. Therefore, any instrumental error can be eliminated between the processing chambers.

When the target holding mechanisms provided around the columnar rotation axis are two in number, the two target holding mechanisms may be arranged in parallel to each other so that the columnar rotation axis is located between the two target holding mechanisms.

According to one preferred embodiment of this invention, the magnetic field generation mechanism forms a circular or elliptic plasma ring extending in a direction crossing an axial direction of the columnar rotation axis on a front face of each of targets held by the plurality of target holding mechanisms, and the plasma ring is moved in parallel to the axial direction of the columnar rotation axis by rotating the rotation magnet group.

According to another preferred embodiment of this invention, the magnetic field generation mechanism includes a plurality of fixing peripheral magnetic shells or ferromagnetic members arranged so as to surround the rotation magnet group. In this case, it is preferable that the plate magnets of the rotation magnet group have a surface magnetized into one of an N-pole and an S-pole, and are attached to the columnar rotation axis in an arrangement pattern in which they are wound on the outer circumferential surface of the columnar rotation axis while they are translated in the form of a belt along with another plate magnet or ferromagnetic member having a surface magnetized into the other pole of the N-pole and the S-pole. It is also preferable that the fixing peripheral magnetic shells are magnetized in a thickness direction and arranged so that one of an N-pole and an S-pole of the fixing peripheral magnetic shells is opposed to the target holding mechanisms.

In one preferred embodiment of this invention, the plate magnets of the rotation magnet group are magnetized in a thickness direction and are attached to the columnar rotation axis in an arrangement pattern in which one or more magnetic pole rings in which N-poles and S-poles are wound in a form of a belt so as to make a round of the columnar rotation axis or form a spiral on the outer circumferential surface of the columnar rotation axis with varying positions in an axial direction of the columnar rotation axis are formed at predetermined intervals in the axial direction of the columnar rotation axis, and the fixing peripheral magnetic shells are magnetized in a thickness direction and arranged so that one of an N-pole and an S-pole of the fixing peripheral magnetic shells is opposed to the target holding mechanisms.

In another preferred embodiment of this invention, the power supply mechanism has a plurality of DC power sources and/or high-frequency power sources electrically connected to the plurality of target holding mechanisms individually. In this case, it is preferable that a conductive cover, electrically grounded, for individually covering high-frequency feeder portions on a rear side of the plurality of target holding mechanisms are provided in order to isolate high frequencies provided to the plurality of target holding mechanisms by the power supply mechanism from each other. In addition, the plurality of target holding mechanisms have a plurality of conductive backing plates for supporting a target at a rear side of the target, and each of the targets is electrically connected to the power supply mechanism via a corresponding backing plate.

In another preferred embodiment of this invention, a conductive cover is provided for individually covering magnetic field spaces on a rear side of the plurality of target holding mechanisms in order to isolate magnetic fields provided to the plurality of target holding mechanisms by the magnetic field generation mechanism from each other.

In another preferred embodiment of this invention, a substrate movement mechanism is provided for moving the substrate in a direction that is in parallel to the target holding mechanism and crosses an axial direction of the columnar rotation axis so that the substrate moves across a sputtering space provided in front of the target holding mechanism within each of the processing chambers. Preferably, components of the apparatus are arranged so that the substrate movement mechanism moves the substrate in a state in which the substrate is substantially in parallel to a direction of gravity. Typically, components of the apparatus are arranged so that the axial direction of the columnar rotation axis substantially accords with the direction of gravity.

A magnetron sputtering apparatus according to this invention may have a structure in which a transport chamber for transporting the substrate under a reduced pressure is provided between the plurality of processing chambers, the substrate is transported between the plurality of processing chambers via the transport chamber, and a deposition process is continuously performed in an in-line manner on the substrate in each of the processing chambers.

A magnetron sputtering apparatus according to a second aspect of this invention comprises a first magnetic field generation mechanism including a first rotation magnet group of a plurality of plate magnets attached to an outer circumferential surface of a first columnar rotation axis in a predetermined arrangement pattern, the first magnetic field generation mechanism being operable to drive rotation of the first rotation magnet group integrally with the first columnar rotation axis, a first target holding mechanism extending in parallel to the first columnar rotation axis such that a rear face of the first target holding mechanism faces the first rotation magnet group, the first target holding mechanism being provided on one side of the first rotation magnet group, a second target holding mechanism extending in parallel to the first columnar rotation axis such that a rear face of the second target holding mechanism faces the first rotation magnet group, the second target holding mechanism being provided on an opposite side of the first rotation magnet group so that the second target holding mechanism is opposed in parallel to the first target holding mechanism, a second magnetic field generation mechanism including a second rotation magnet group of a plurality of plate magnets attached to an outer circumferential surface of a second columnar rotation axis extending in parallel to the first columnar rotation axis at a position spaced from the first columnar rotation axis in a predetermined arrangement pattern, the second magnetic field generation mechanism being operable to drive rotation of the second rotation magnet group integrally with the second columnar rotation axis, a third target holding mechanism extending in parallel to the second columnar rotation axis such that a rear face of the third target holding mechanism faces the second rotation magnet group, the third target holding mechanism being substantially flush with the first target holding mechanism and being provided on one side of the second rotation magnet group, a fourth target holding mechanism extending in parallel to the second columnar rotation axis such that a rear face of the fourth target holding mechanism faces the second rotation magnet group, the fourth target holding mechanism being opposed in parallel to the third target holding mechanism, being substantially flush with the second target holding mechanism, and being provided on an opposite side of the second rotation magnet group, first, second, third, and fourth processing chambers that receive substrates to be processed in a state in which the substrates are opposed to front faces of the first, second, third, and fourth target holding mechanisms so that the substrates can be transported into and from the processing chambers, the processing chambers being capable of decompression, a gas supply mechanism for supplying a sputtering gas to the first, second, third, and fourth processing chambers; and a power supply mechanism for supplying electric power for electric discharge to the first, second, third, and fourth target holding mechanisms to generate plasma of the sputtering gas in the first, second, third, and fourth processing chambers. In this case, a magnetic field for confining the plasma of the sputtering gas is formed for the first and second target holding mechanisms by the first magnetic field generation mechanism so that a sputtering process can be performed in the first and second processing chambers, and a magnetic field for confining the plasma of the sputtering gas is formed for the third and fourth target holding mechanisms by the second magnetic field generation mechanism so that a sputtering process can be performed in the third and fourth processing chambers.

In the second aspect of the magnetron sputtering apparatus, thin films of the same material or different materials can simultaneously be formed on four substrates in four processing chambers with four targets by using the parallel arrangement of the first and second processing chambers with respect to the first magnetic field generation mechanism and the parallel arrangement of the third and fourth processing chambers with respect to the second magnetic field generation mechanism. Stacking formation of thin films of the same material or different materials can smoothly be performed with efficiency by the series arrangement of the first and third processing chambers and the series arrangement of the second and fourth processing chambers.

According to one preferred embodiment of this invention, a first substrate movement mechanism is provided for moving a first substrate to be processed in a direction that is in parallel to the first and third target holding mechanisms and is perpendicular to axial directions of the first and second columnar rotation axis so that the first substrate moves sequentially across the first and third sputtering spaces respectively provided in front of the first and third target holding mechanisms within the first and third processing chambers and a second substrate movement mechanism is also provided for moving a second substrate to be processed in a direction that is in parallel to the second and fourth target holding mechanisms and is perpendicular to the axial directions of the first and second columnar rotation axis so that the second substrate moves sequentially across the second and fourth sputtering spaces respectively provided in front of the second and fourth target holding mechanisms within the second and fourth processing chambers.

A magnetron sputtering apparatus according to a third aspect of this invention comprises a magnetic field generation mechanism including a rotation magnet group of a plurality of magnetic shells attached to an outer circumferential surface of a columnar rotation axis in a predetermined arrangement pattern, the magnetic field generation mechanism being operable to drive rotation of the rotation magnet group integrally with the columnar rotation axis, a plurality of target holding mechanisms each extending in parallel to the columnar rotation axis such that a rear face of each of the target holding mechanisms faces the rotation magnet group, the plurality of target holding mechanisms being provided around the rotation magnet group so that the target holding mechanisms do not overlap in a radial direction of the columnar rotation axis, a processing chamber that collectively receives the plurality of target holding mechanisms and receives a substrate to be processed so that the substrate can be transported into and from the processing chamber, the processing chamber being capable of decompression, an index transportation mechanism for integrally moving the plurality of target holding mechanisms around the columnar rotation axis in a circumferential direction in order to align any one of the plurality of target holding mechanisms, as an operating target holding mechanism, with a predetermined operational position opposed to a regular sputtering space defined in the processing chamber, a gas supply mechanism for supplying a sputtering gas to the processing chamber; and a power supply mechanism for supplying electric power for electric discharge to the operating target holding mechanism in the processing chamber to discharge in the sputtering gas within the regular sputtering space. In this case, a magnetic field for confining plasma of the sputtering gas is formed for the operating target holding mechanism by the magnetic field generation mechanism so that a sputtering process can be performed in the regular sputtering space.

In the third aspect of the magnetron sputtering apparatus, a sputtering deposition can successively be performed on one substrate to form thin films of the same material or different materials by selecting or switching into an operating target holding mechanism used for the sputtering deposition process from among a plurality of target holding mechanisms with the index transportation mechanism.

In one preferred embodiment of this invention, a dummy sputtering space is provided in the processing chamber at a position opposed to one or more target holding mechanisms of the plurality of target holding mechanisms other than the operating target holding mechanism, the power supply mechanism supplies electric power for electric discharge to a non-operating target holding mechanism to discharge in the sputtering gas within the dummy sputtering space, and a magnetic field for confining plasma of the sputtering gas is formed for the non-operating target holding mechanism by the magnetic field generation mechanism so that a dummy sputtering process can be performed in the dummy sputtering space.

Preferably, a dummy sputtering attachment prevention portion for receiving and depositing sputtering particles emitted from a target held by the non-operating target holding mechanism to the dummy sputtering space can be provided.

### Effect(s) of the Invention

According to a magnetron sputtering apparatus of the present invention, a sputtering efficiency and a production efficiency in a magnetron sputtering method can remarkably be improved with the aforementioned configuration and effects.

### BRIEF DESCRIPTION OF DRAWINGS

FIG. 1 is a schematic cross-sectional view showing a configuration of a magnetron sputtering apparatus in a first embodiment of the present invention.

FIG. 2A is a perspective view showing an overview of a sputtering gun unit (primarily a left-side side surface thereof) that is incorporated into the magnetron sputtering apparatus according to the embodiment.

FIG. 2B is a perspective view showing an overview of the sputtering gun unit (primarily a right-side side surface thereof) that is incorporated into the magnetron sputtering apparatus according to the embodiment.

FIG. 3 is a bird's-eye view of a primary portion of a magnetic field generation mechanism in the magnetron sputtering apparatus according to the embodiment and a view as seen from a target.

FIG. 4A is a perspective view showing a plasma ring generation region in the magnetron sputtering apparatus according to the embodiment.

FIG. 4B is a perspective view showing the plasma ring generation region in the magnetron sputtering apparatus according to the embodiment.

FIG. 5A is a diagram showing another configuration example of a rotation magnet group in the magnetron sputtering apparatus according to the embodiment.

FIG. 5B is a diagram showing another configuration example of the rotation magnet group in the magnetron sputtering apparatus according to the embodiment.

FIG. 6 is a diagram schematically showing an example in which a plurality of sputtering gun units are arranged in a row in the magnetron sputtering apparatus according to the embodiment.

FIG. 7 is a schematic plan view showing a layout of an in-line system for manufacturing an organic EL display according to an embodiment.

FIG. 8A is a schematic cross-sectional view showing a step of a manufacturing process of an organic EL display.

FIG. 8B is a schematic cross-sectional view showing a step of the manufacturing process of an organic EL display.

FIG. 8C is a schematic cross-sectional view showing a step of the manufacturing process of an organic EL display.

FIG. 9A is a schematic cross-sectional view showing a step of the manufacturing process of an organic EL display.

FIG. 9B is a schematic cross-sectional view showing a step of the manufacturing process of an organic EL display.

FIG. 9C is a schematic cross-sectional view showing a step of the manufacturing process of an organic EL display.

FIG. 9D is a schematic cross-sectional view showing a step of the manufacturing process of an organic EL display.

FIG. 10 is a schematic plan view showing another layout of the in-line system for manufacturing an organic EL display according to another embodiment.

FIG. 11 is a schematic plan view showing another layout of the in-line system for manufacturing an organic EL display according to another embodiment.

FIG. 12 is a schematic plan view showing a layout of an in-line system for manufacturing a solar cell according to an embodiment.

FIG. 13A is a schematic cross-sectional view showing a step of a manufacturing process of a solar cell.

FIG. 13B is a schematic cross-sectional view showing a step of the manufacturing process of a solar cell.

FIG. 13C is a schematic cross-sectional view showing a step of the manufacturing process of a solar cell.

FIG. 13D is a schematic cross-sectional view showing a step of the manufacturing process of a solar cell.

FIG. 13E is a schematic cross-sectional view showing a step of the manufacturing process of a solar cell.

FIG. 13F is a schematic cross-sectional view showing a step of the manufacturing process of a solar cell.

FIG. 14 is a schematic cross-sectional view showing an example of a structure of a tandem solar cell.

FIG. 15 is a schematic plan view showing a layout of an in-line system for manufacturing a solar cell according to another embodiment.

FIG. 16 is a schematic cross-sectional view showing a configuration of a magnetron sputtering apparatus according to another embodiment.

### MODE(S) FOR CARRYING OUT THE INVENTION

Preferred embodiments of the present invention will be described below with reference to the accompanying drawings.

### First Embodiment

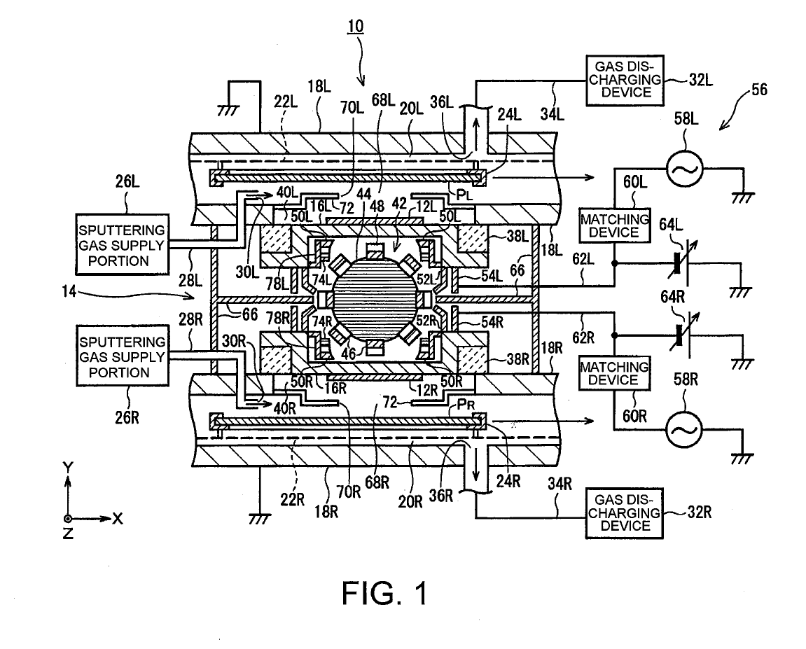

A magnetron sputtering apparatus according to a first embodiment of the present invention will be described with reference to FIGS. 1 to 6.

FIG. 1 shows a configuration of a magnetron sputtering apparatus 10 in this embodiment.

The magnetron sputtering apparatus 10 is formed as a vertical-passing-type sputtering apparatus for performing a sputtering deposition process while moving (passing) substrates P as substrates to be processed in a state in which the substrates P are vertically raised (i.e., in such a position that the substrates P are substantially in parallel to a direction of gravity). The magnetron sputtering apparatus 10 is formed as a sputtering apparatus capable of simultaneously processing two substrates with targets 12L and 12R as twin targets of bilateral symmetry (symmetry between the upper target and the lower target in FIG. 1).

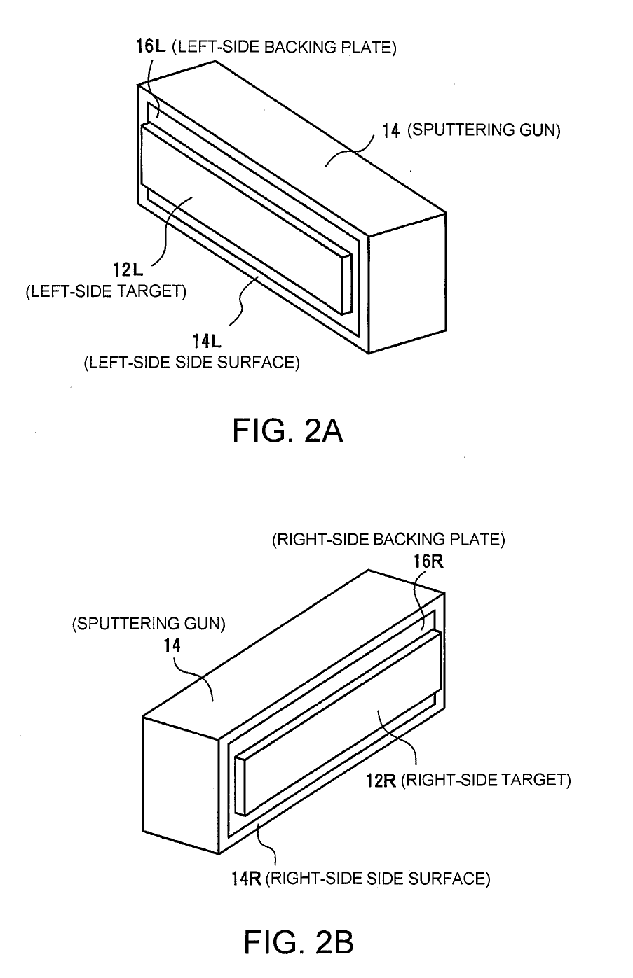

FIGS. 2A and 2B schematically show appearance (particularly bilateral symmetry) of a double-head sputtering gun mounted on the magnetron sputtering apparatus 10. As illustrated in FIGS. 2A and 2B, targets 12L and 12R in the form of an elongated rectangular flat plate are respectively mounted on a left-side side surface 14L and a right-side side surface 14R of one sputtering gun unit 14 in a state in which they are attached to backing plates 16L and 16R. Both of the targets 12L and 12R are made of any material (metal, insulating material, or the like), which will be a material for a thin film. The materials and sizes of the targets 12L and 12R may be the same or different. The backing plates 16L and 16R are made of any conductive material. Generally, a copper-based metal is used for the backing plates 16L and 16R. A magnetic field generation mechanism 42 including movable magnets (a rotation magnet group 48) for a magnetron discharge, which will be described later, is provided inside of the sputtering gun unit 14 (FIG. 1).

In FIG. 1, vacuum chambers 18L and 18R capable of decompression are coupled to the left side and the right side of the sputtering gun unit 14. Those chambers 18L and 18R are made of, for example, aluminum and are electrically grounded for safety. The chambers 18L and 18R respectively form hallway-like processing chambers 20L and 20R extending straight in the horizontal direction (X-direction) parallel to the plate surfaces of the targets 12L and 12R.

Substrate transport paths 22L and 22R for moving the substrates P_{L} and P_{R} to be processed along the X-direction are respectively laid in the chambers 18L and 18R as schematically indicated by dotted lines. For example, vertically-oriented trays 24L and 24R for holding the substrates P_{L} and P_{R} in the vertical position are movable on the substrate transport paths 22L and 22R. A transport drive portion including a linear motor (not shown) or the like is operable to drive transportation of the vertically-oriented trays 24L and 24R together with the substrates P_{L} and P_{R}.

Gas supply ports 30L and 30R respectively connected to gas supply pipes 28L and 28R from sputtering gas supply portions 26L and 26R, discharge ports 36L and 36R respectively connected to discharge pipes 34L and 34R connected to gas-discharging devices 32L and 32R, and the like are formed in sidewalls, bottoms, or ceilings of the chambers 18L and 18R. Furthermore, transport inlet and outlet capable of opening and closing, which are omitted from the illustration, are provided on both ends of each of the chambers 18L and 18R in the longitudinal direction (X-direction) for loading and unloading the substrates P.

The backing plates 16L and 16R, which are disposed on the left-side side surface and the right-side side surface of the sputtering gun unit 14, are respectively attached so as to close rectangular openings 40L and 40R formed in inner walls of the chambers 18L and 18R with insulators 38L and 38R, which are in the form of a rectangular frame. Each of the backing plates 16L and 16R has a passage for allowing a cooling medium, which is supplied from a chiller device or the like in a circulated manner, to flow therethrough. Those passages are omitted from the illustration.

The magnetic field generation mechanism 42 for forming a leakage magnetic field for a magnetron discharge on front faces of the targets 12L and 12R is provided in rear spaces of the backing plates 16L and 16R, i.e., in a space between the backing plates (16L and 16R). The magnetic field generation mechanism 42 has a rotation magnet group 48 including a plurality of plate magnets 46 attached to an outer circumferential surface of one columnar rotation axis 44 in a predetermined arrangement pattern, a rotation drive portion (not shown) for driving rotation of the rotation magnet group 48 together with the columnar rotation axis 44, and fixing peripheral magnetic shells 50L and 50R for forming part of the leakage magnetic field on the front faces of the targets 12L and 12R between some of the magnets in the rotation magnet group 48 and the fixing peripheral magnetic shells 50L and 50R. The configuration and operation of respective components of the magnetic field generation mechanism 42 will be described later in detail.

Cylindrical magnetic covers 52L and 52R are attached to rear faces of the backing plates 16L and 16R so as to individually cover magnetic field spaces on rear sides of the targets 12L and 12R, respectively. Those magnetic covers 52L and 52R serve as magnetic shields for confining magnetic fields provided to the targets 12L and 12R by the magnetic field generation mechanism 42 in the interiors of the magnetic covers 52L and 52R so as to isolate those magnetic fields from each other and for preventing (blocking) influence from external surrounding magnetic fields.

Furthermore, cylindrical feeder members 54L and 54R made of, for example, aluminum are attached to the rear faces of the backing plates 16L and 16R at positions outside of the magnetic covers 52L and 52R from the magnetic field generation mechanism 42. The feeder members 54L and 54R constitute feed paths or transmission paths for introducing electric power for electric discharge.

A power supply mechanism 56 for supplying electric power for electric discharge includes high-frequency/DC power sources dedicated to the left and right-side targets 12L and 12R, respectively.

A high-frequency power source 58L is electrically connected to the left-side backing plate 16L via a matching device 60L, a feeder line 62L, and the feeder member 54L. A first DC power source 64L is also electrically connected to the left-side backing plate 16L via the feeder line 62L and the feeder member 54L. When the target 12L is dielectric, only the high-frequency power source 58L is used. When the target 12L is made of metal, only the DC power source 64L or both of the DC power source 64L and the high-frequency power source 58L are used.

A high-frequency power source 58R is electrically connected to the right-side backing plate 16R via a matching device 60R, a feeder line 62R, and the feeder member 54R. A second DC power source 64R is also electrically connected to the right-side backing plate 16R via the feeder line 62R and the feeder member 54R. When the target 12R is dielectric, only the high-frequency power source 58R is used. When the target 12R is made of metal, only the DC power source 64R or both of the DC power source 64R and the high-frequency power source 58R are used.

Furthermore, a conductive cover 66 is attached to the chambers 18L and 18R at a position outside of the feeder members 54L and 54R from the magnetic field generation mechanism 42. The conductive cover 66 extends so as to be inserted between the left and right feeder members 54L and 54R and also between the left and right magnetic covers 52L and 52R. The conductive cover 66 is made of, for example, aluminum and is electrically grounded via the chambers 18L and 18R. The conductive cover 66 serves to isolate high frequencies provided to the targets 12L and 12R by the power supply mechanism 56 from each other.

Sputtering spaces 68L and 68R are respectively defined in front of the targets 12L and 12R within the chambers 18L and 18R. Slits 70L and 70R are respectively formed to limit, to desired shape and size, sputtering areas of processing surfaces of the substrates P_{L} and P_{R} that are moved across the sputtering spaces 68L and 68R in the X-direction. Plate members 72 for forming the slits 70L and 70R are made of a conductive material such as aluminum and are coupled physically and electrically to the chambers 18L and 18R. The plate members 72 serve as ground plates for exciting plasma efficiently even if the substrates P_{L} and P_{R} are in an electrically floating state.

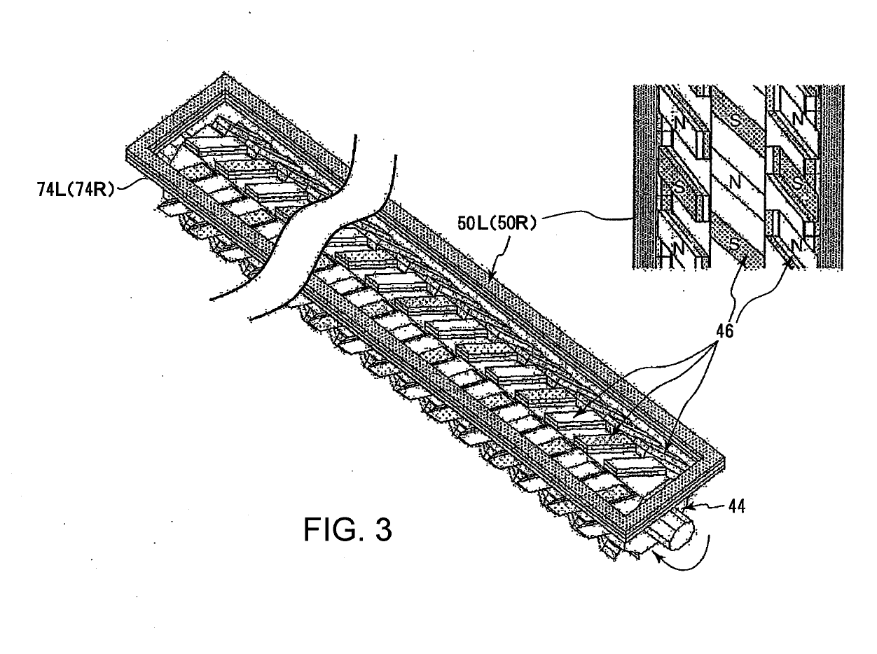

FIG. 3 is a bird's-eye view of the columnar rotation axis 44 and the rotation magnet group 48, which constitute the magnetic field generation mechanism 42, a large number of plate magnets 46, which constitute the rotation magnet group 48, the fixing peripheral magnetic shell 50L (50R), and a paramagnetic member 74L (74R), and a plan view as seen from the backing plate 16L (16R).

The columnar rotation axis 44 is made of, for example, a Ni—Fe based alloy having a high magnetic permeability, is connected to a motor via a transmission mechanism, which is not shown in the drawings, and is driven to rotate at a desired rotational speed (e.g., 600 rpm).

The columnar rotation axis 44 has an outer circumferential surface of a polygon, for example, a regular octagon. A large number of rhombus plate magnets 46 are attached to each surface of the octahedron with a predetermined arrangement. A Sm—Co based sintered magnet having a residual flux density of about 1.1 T or a Nd—Fe—B based sintered magnet having a residual flux density of about 1.3 T can suitably be used for those plate magnets 46. Each of the plate magnets 46 is magnetized in a direction perpendicular to its plate surface (in the thickness direction). The plate magnets 46 are spirally attached to the columnar rotation axis 44 so as to form a plurality of spirals. Adjacent spirals in the axial direction of the columnar rotation axis 44 have different magnetic poles, i.e., an N-pole and an S-pole, on a radial outside surface of the columnar rotation axis 44. In other words, N-pole belts and S-pole belts are spirally wound around the outer circumferential surface of the common columnar rotation axis 44 while they are translated along the outer circumferential surface of the common columnar rotation axis 44.

The fixing peripheral magnetic shell 50L (50R) is formed as a rectangular frame so as to surround the rotation magnet group 48 at a position close to the target 12L (12R). A surface of the fixing peripheral magnetic shell 50L (50R) that faces the target 12L (12R) or the backing plate 16L (16R) is an S-pole, whereas the opposite surface of the fixing peripheral magnetic shell 50L (50R) is an N-pole. For example, the fixing peripheral magnetic shell 50L (50R) may also be formed of a Nd—Fe—B based sintered magnet.

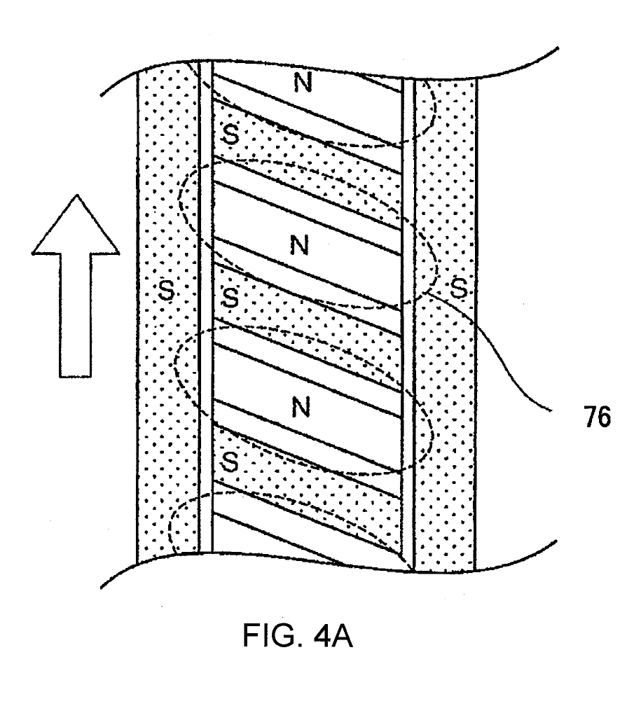

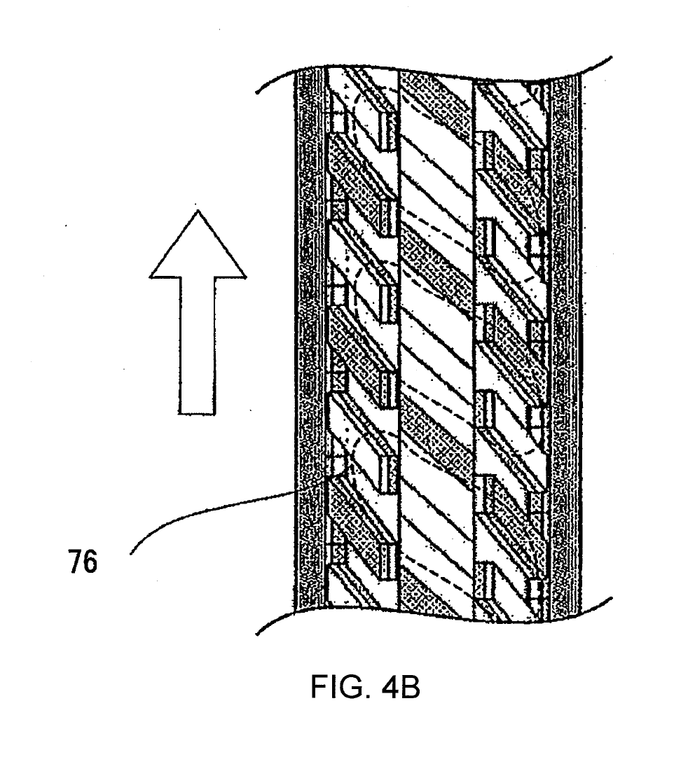

When a large number of plate magnets 46 are spirally arranged on the columnar rotation axis 44 as described above, the N-poles of the plate magnets 46, which extend in the form of a belt on a surface facing the target 12L (12R), are approximately surrounded by the S-poles of other neighboring plate magnets 46 and the fixing peripheral magnetic shell 50L (50R) as shown in FIG. 4A. Thus, part of lines of magnetic force from the N-pole of the plate magnet 46 draws a curve, passes through the backing plate 16L (16R), comes out of the front face of the target 12L (12R), then passes through the backing plate 16L (16R) in the opposite direction, and terminates at the neighboring S-poles. Here, a horizontal component of the leakage magnetic field on the front face of the target 12L (12R) contributes to capturing secondary electrons with a Lorentz force.

According to the magnetic field generation mechanism 42 having the above configuration, secondary electrons or plasma is confined in plasma rings 76, which have an elliptical loop pattern as indicated by dotted lines of FIGS. 4A and 4B, on the front face of the target 12L (12R). A large number of plasma rings 76 having the same shape can be generated in a state in which they are arranged in the axial direction. Each of those plasma rings 76 has a major axis corresponding to the width of the fixing peripheral magnetic shell 50L (50R) and a minor axis corresponding to the spiral pitch. Therefore, the size of the major axis of each of the plasma rings 76 can be adjusted so as to cover a range from one end to another end of the target by selecting the width of the fixing peripheral magnetic shell 50L (50R) depending upon the width of the target 12L (12R). By driving the columnar rotation axis 44 to rotate, each of the plasma rings 76 can be moved in a direction corresponding to the rotational direction of the columnar rotation axis 44 at a speed corresponding to the rotational speed of the columnar rotation axis 44 along the axial direction, i.e., along the longitudinal direction of the target.

The paramagnetic member 74L (74R), which has the same shape as the fixing peripheral magnetic shell 50L (50R), is attached to the rear face of the fixing peripheral magnetic shell 50L (50R) as seen from the target 12L (12R). The paramagnetic member 74L or 74R is connected to the backing plate 16L (16R) and the magnetic cover 52L (52R) via a plate joint 78L or 78R, which is made of a paramagnetic material. Lines of magnetic force from the rear face (N-pole) of the fixing peripheral magnetic shell 50L (50R) enter the paramagnetic member 74L (74R) and do not diffuse externally.

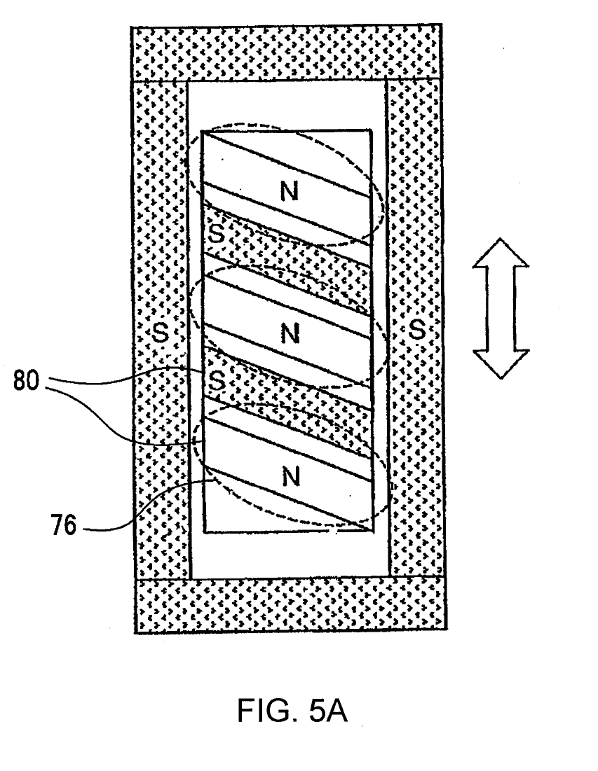

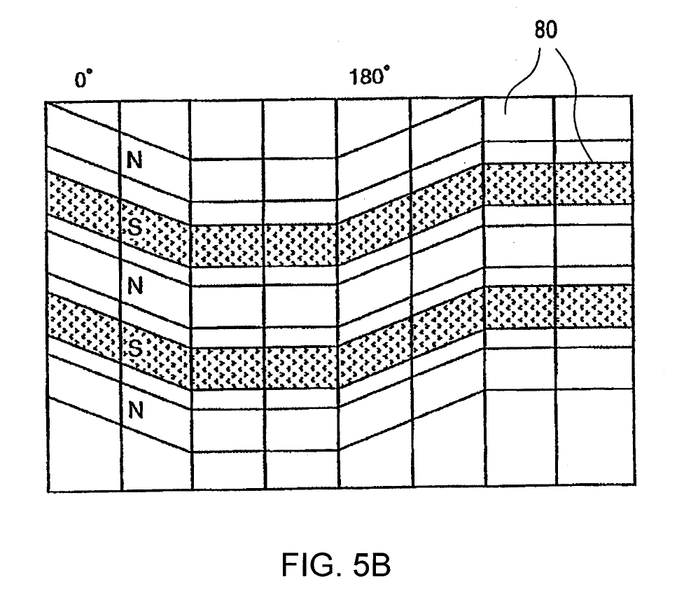

FIG. 5A shows another configuration example of the rotation magnet group 48. In this configuration example, the rotation magnet group 48 has an arrangement pattern in which a large number of magnetic pole rings 80 are formed with a predetermined pitch in the axial direction of the columnar rotation axis 44 such that each of N-pole belts and S-pole belts makes a round of the columnar rotation axis 44 with varying positions in the axial direction of the columnar rotation axis 44 on the outer circumferential surface of the columnar rotation axis 44. A large number of plate magnets 46 are attached to the outer circumferential surface of the columnar rotation axis 44.

More specifically, adjacent magnetic pole rings (ringlike magnetic shell group) 80 in the axial direction of the columnar rotation axis 44 have opposite magnetic poles (an N-pole and an S-pole) on the front face thereof. The position of each of the magnetic pole rings 80 varies in the axial direction with a predetermined pattern during one round of the columnar rotation axis 44 in the circumferential direction.

FIG. 5B shows a development of the surface of the columnar rotation axis 44 and the rotation magnet group 48. As shown in FIG. 5B, each of the magnetic pole rings 80 varies its position along the circumferential direction of the columnar rotation axis 44 in the axial direction. Each of the magnetic pole rings 80 has a pattern in which the position of the magnetic pole ring 80 varies by a predetermined amount (e.g., the amount corresponding to 1 pitch) with rotation of 180° and returns to the initial position with rotation of 360°.

With this configuration example, when the rotation magnet group 48 is rotated in one direction (e.g., clockwise) along with the columnar rotation axis 44, the plasma rings 76 are reciprocated (swung) in the longitudinal direction of the target on the front face of the target 12L (12R).

In the magnetic field generation mechanism 42 of this embodiment, the width or pitch of the spiral portions may differ between the N-pole spiral portion (or the N-pole rings) and the S-pole spiral portion (or the S-pole rings).

In the magnetic field generation mechanism 42, the fixing peripheral magnetic shell 50L (50R) may be made of a ferromagnetic material. The paramagnetic member 74L (74R) may be replaced with another magnetic member, e.g., a ferromagnetic member.

Next, overall operation of the magnetron sputtering apparatus will be described. When the magnetron sputtering apparatus is operated, a sputtering gas (e.g., Ar gas) is introduced into the sealed chambers 18L and 18R from the sputtering gas supply portions 26L and 26R at a predetermined flow rate. The pressure in the chambers 18L and 18R is set to be a preset value by the gas-discharging devices 32L and 32R. Furthermore, the high-frequency power sources 58L and 58R and/or the DC power sources 64L and 64R are turned on. High-frequency voltages and/or DC voltages having a predetermined frequency (e.g., 13.56 MHz) are respectively applied to both of the targets 12L and 12R as cathodes with a predetermined power.

Furthermore, the magnetic field generation mechanism 42 in the sputtering gun unit 14 is turned on. Plasma generated near the front faces of the targets 12L and 12R by a magnetron discharge is confined in the form of a ring. The ringlike plasma (plasma rings) is moved in a predetermined direction (in the longitudinal direction of the target, i.e., in the Z-direction). Sputtering particles are emitted from the front faces of the targets 12L and 12R, respectively, by injection of ions from the plasma rings.

Meanwhile, the vertically-oriented trays 24L and 24R hold the substrates P_{L} and P_{R} in the vertical position within the chambers 18L and 18R and move along the substrate transport paths 22L and 22R in the X-direction so that the substrates P_{L} and P_{R} move across the sputtering spaces 68L and 68R in the X-direction. Thus, the sputtering particles that have been emitted from the targets 12L and 12R and have passed through the slits 70L and 70R are injected into the processing surfaces of the substrates P_{L} and P_{R} passing through the sputtering spaces 68L and 68R and are deposited thereon.

With such a scanning method, a sputtering deposition is simultaneously performed from one ends to other ends of the substrates P_{L} and P_{R} in the X-direction, so that a thin film is simultaneously formed on the entire processing surfaces of the substrates P_{L} and P_{R}. As described above, materials of the targets 12L and 12R can be selected independently of each other. Thus, thin films of the same material or different materials can simultaneously be formed on the two substrates P_{L} and P_{R} with a single apparatus.

Furthermore, the magnetic field generation mechanism 42, which exerts the largest influence on the magnetron discharge characteristics, is used in common to the left and right chambers 18L and 18R. Therefore, any instrumental error can be eliminated between the chambers 18L and 18R.

The substrates P_{L} and P_{R} may be moved in opposite directions along the substrate transport paths 22L and 22R within the left and right chambers 18L and 18R.

As described above, the magnetron sputtering apparatus of this embodiment has twin targets 12L and 12R provided on two surfaces (the left-side side surface and the right-side side surface) opposed to each other in the single sputtering gun unit 14, which is substantially in the form of a rectangular parallelepiped. Thin films of the same material or different materials can simultaneously be formed on the two substrates Pᵢ and Pⱼ at both of the left and right sides of the sputtering gun unit 14. Thus, a throughput and a production efficiency equivalent to those of two apparatuses can be achieved with a single apparatus having a compact structure.

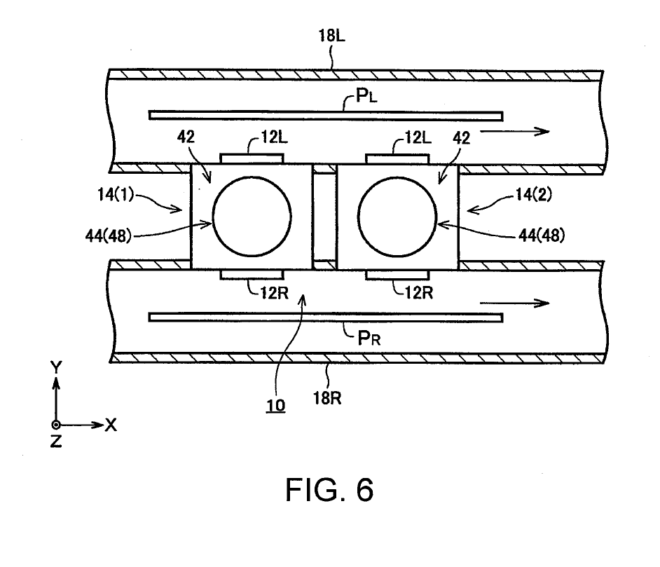

As one application of this embodiment, a plurality of sputtering gun units 14(1), 14(2), . . . may be arranged in a row or in series along the moving direction of the substrates Pᵢ and Pⱼ (X-direction) as shown in FIG. 6. With this configuration, the effects of doubling the production efficiency according to the present invention can further be enhanced.

### Second Embodiment

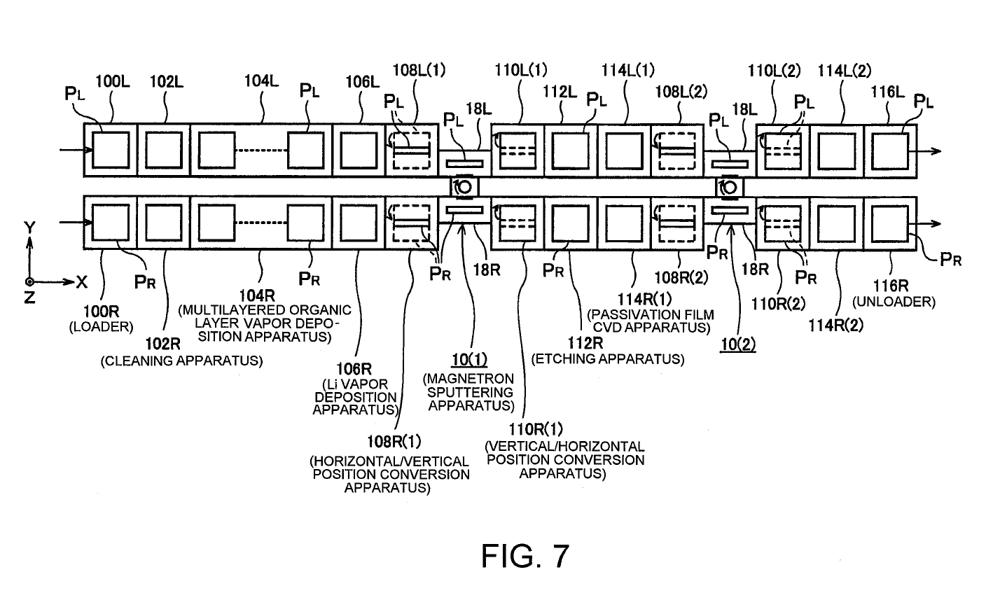

Next, an in-line system for manufacturing an organic EL display will be described as a preferred application of the magnetron sputtering apparatus 10 of the embodiment with reference to FIGS. 7 to 9D.

As shown in FIG. 7, this in-line system includes a pair of loaders 100L and 100R, a pair of cleaning apparatuses 102L and 102R, a pair of multilayered organic layer vapor deposition apparatuses 104L and 104R, a pair of Li vapor deposition apparatuses 106L and 106R, a pair of first horizontal/vertical position conversion apparatuses 108L(1) and 108R(1), a first vertical type magnetron sputtering apparatus 10(1), a pair of first vertical/horizontal position conversion apparatuses 110L(1) and 110R(1), a pair of etching apparatuses 112L and 112R, a pair of first passivation film CVD (Chemical Vapor Deposition) apparatuses 114L(1) and 114R(1), a pair of second horizontal/vertical position conversion apparatuses 108L(2) and 108R(2), a second vertical type magnetron sputtering apparatus 10(2), a pair of second vertical/horizontal position conversion apparatuses 110L(2) and 110R(2), a pair of second passivation film CVD apparatuses 114L(2) and 114R(2), and a pair of unloaders 116L and 116R arranged in two rows of the left and right rows along one direction (X-direction) in order named.

Among the group of apparatuses in the above lines, the loaders 100L and 100R at the first stage introduce unprocessed substrates P_{L} and P_{R} under the atmospheric pressure, change internal pressures from the atmospheric pressure into a reduced pressure, and transfer the substrates P_{L} and P_{R} to the subsequent cleaning apparatuses 102L and 102R. All of the apparatuses from the cleaning apparatuses 102L and 102R to the second passivation film CVD apparatuses 114L(2) and 114R(2) are pressure-reducible apparatuses or pressure-reducible position conversion apparatuses. The unloaders 116L and 116R at the final stage receive the processed substrates P_{L} and P_{R} from the second passivation film CVD apparatuses 114L(2) and 114R(2) under a reduced pressure, change internal pressures from the reduced pressure to the atmospheric pressure, and transfer the substrates P_{L} and P_{R} to the exterior of the system under the atmospheric pressure.

In FIG. 7, P_{L} denotes a substrate subject to a series of processes in the left process line (100L-116L), whereas P_{R} denotes a substrate subject to a series of processes in the right process line (100R-116R).

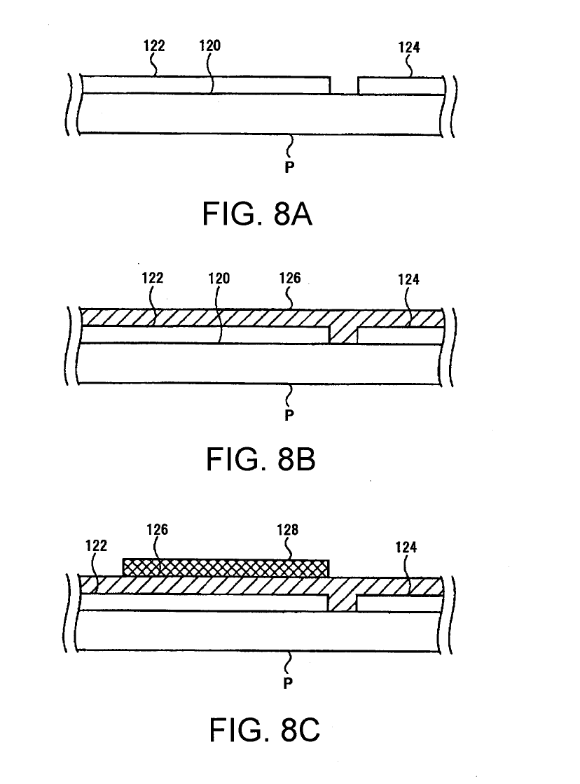

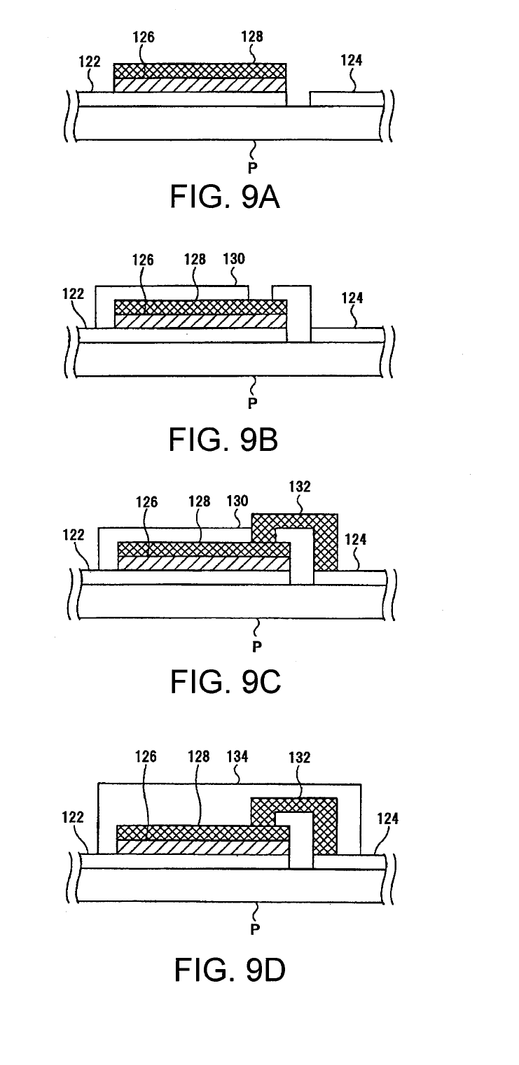

A process of manufacturing an organic EL display with this in-line system will be described with reference to FIGS. 8A to 9D.

First, the substrates P_{L} and P_{R} transferred into the loaders 100L and 100R are formed of a transparent plate such as glass or a sheet. As shown in FIG. 8A, an anode electrode 122 made of a transparent conductive material such as ITO (Indium Tin Oxide) and a lead 124 for a cathode electrode 128, which is formed in a later process, are formed on a device formation surface 120 in advance.

The substrates P_{L} and P_{R} are transported in the horizontal position to the loaders 100L and 100R. Processing surfaces of the substrates P_{L} and P_{R} are cleaned in the adjacent cleaning apparatuses 102L and 102R by, for example, a dry cleaning method while the horizontal position of the substrates P_{L} and P_{R} is maintained.

Then the substrates P_{L} and P_{R} are transported in the X-direction within the multilayered organic layer vapor deposition apparatuses 104L and 104R while the horizontal position of the substrates P_{L} and P_{R} is maintained. During the transportation, an organic layer in which multiple layers (e.g., six layers) are stacked is formed on the substrates by a vapor deposition method. Specifically, as shown in FIG. 8B, an organic layer 126 having six layers including a light-emitting layer (organic EL layer) is formed so as to cover an exposed portion of the anode electrode 122, the lead 124, and the device formation surface 120 of each of the substrates P_{L} and P_{R}. No mask is used for this vapor deposition process. The organic layer 126 is adhered substantially to the entire surface of each substrate.

This vapor deposition process is performed in a state in which the processing surfaces of the substrates P_{L} and P_{R} face upward, i.e., in a face-up state. In order to perform a face-up vapor deposition, the multilayered organic layer vapor deposition apparatuses 104L and 104R are configured to first carry a deposition material gas to the substrates P and to supply the deposition material gas from above the substrates P_{L} and P_{R}.

After the organic layer having a multilayered structure has been adhered to the entire surfaces of the substrates P_{L} and P_{R} in the multilayered organic layer vapor deposition apparatuses 104L and 104R, the substrates P_{L} and P_{R} are transported to the Li vapor deposition apparatuses 106L and 106R, where a Li film (not shown), which serves as a film for adjusting a work function, is adhered onto the organic layer 126 by a vapor deposition method. Then the substrates P_{L} and P_{R} are converted from the horizontal position into the vertical position within the first horizontal/vertical position conversion apparatuses 108L(1) and 108R(1) and transported to the first vertical type magnetron sputtering apparatus 10(1) according to the present embodiment.

In the magnetron sputtering apparatus 10(1), a cathode electrode 128 made of, for example, a Ag film is formed on the substrates P_{L} and P_{R} as shown in FIG. 8C by, for example, a sputtering method using a pattern mask.

Subsequently, the substrates P_{L} and P_{R} are converted from the vertical position to the horizontal position within the first vertical/horizontal position conversion apparatuses 110L(1) and 110R(1) and transported into the etching apparatuses 112L and 112R in the horizontal position. The etching apparatuses 112L and 112R perform an etching process on the organic layer 126 with use of a mask of the patterned cathode electrode 128 by, for example, a plasma etching method, so that the organic layer 126 is patterned as shown in FIG. 9A. This etching process may be performed in a face-up state in which the processing surfaces of the substrates P_{L} and P_{R} face upward.

Next, the substrates P_{L} and P_{R} are transported to the first passivation film CVD apparatuses 114L(1) and 114R(1), where a protective film is formed on the substrates P_{L} and P_{R} by a CVD method using a pattern mask while the substrates P_{L} and P_{R} are in a face-up state. Specifically, as shown in FIG. 9B, an insulative protective film 130 made of, for example, silicon nitride (SiN) is formed by patterning so as to cover part of the anode electrode 122, the organic layer 126, and the cathode electrode 128.

Then the substrates P_{L} and P_{R} are converted from the horizontal position into the vertical position within the second horizontal/vertical position conversion apparatuses 108L(2) and 108R(2) and transported to the second vertical type magnetron sputtering apparatus 10(2) according to the present embodiment.

In the magnetron sputtering apparatus 10(2), as shown in FIG. 9C, a connection line 132 for electrically connecting the cathode electrode 128 and the lead 124 to each other via an opening portion are formed by patterning with, for example, a sputtering method using a pattern mask.

Subsequently, the substrates P_{L} and P_{R} are converted from the vertical position into the horizontal position within the second vertical/horizontal position conversion apparatuses 110L(2) and 110R(2) and transported to the second passivation film CVD apparatuses 114L(2) and 114R(2) in the horizontal position. In the second passivation film CVD apparatuses 114L(2) and 114R(2), a protective film is formed on the substrates P_{L} and P_{R} by a CVD method using a pattern mask while the substrates P_{L} and P_{R} are in a face-up state. Specifically, as shown in FIG. 9D, an insulative protective film 134 made of, for example, silicon nitride (SiN) is formed so as to cover the connection line 132 and part of the lead 124.

Thus, a series of processes in this in-line system is completed. The processed substrates P_{L} and P_{R} are taken out of the unloaders 116L and 116R.

As described above, in this in-line system, two vertical type magnetron sputtering apparatuses 10(1) and 10(2) are simultaneously operated in two lines of left and right process lines. Each of the vertical type magnetron sputtering apparatuses 10(1) and 10(2) has a performance equivalent to that of two magnetron sputtering apparatuses.

For example, if the tact time of one magnetron sputtering apparatus 10 according to the present embodiment is considerably shorter than the tact time of one of the other processing apparatuses, the layout of the process lines can be modified so as to arrange the tact time in the same length. For example, it is assumed that a period of time required for an organic layer deposition process of one substrate P in the organic layer deposition processing portion is 6 minutes and that a period of time required for a sputtering deposition process of one substrate P in the magnetron sputtering apparatus 10 is 3 minutes. In this case, four lines of the organic layer deposition process portions are provided in parallel, and only one magnetron sputtering apparatus 10 is required for those four lines.

Furthermore, the magnetron sputtering apparatus 10 according to the present embodiment performs a deposition process so that the substrate P takes the vertical (standing) position. Therefore, the footprint can also be reduced from this point of view. Moreover, the interior of the sputtering gun unit 14 (particularly the magnetic field generation mechanism 42) can be accessed with ease, so that the maintainability can be enhanced. Furthermore, a warp of a large substrate can be managed with ease, so that the productivity of organic EL displays using large substrates can advantageously be improved.

### Third Embodiment

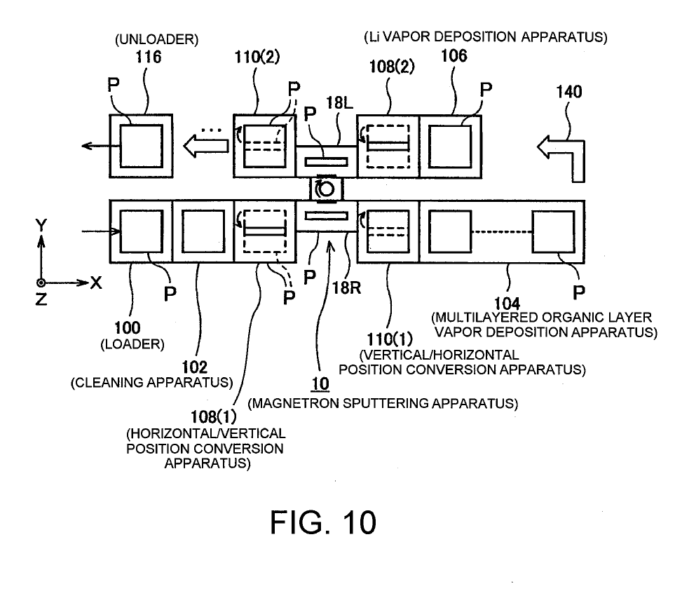

FIG. 10 shows another layout of the in-line system for manufacturing an organic EL display that includes a magnetron sputtering apparatus 10 according to the present embodiment.

This system includes a loader 100, a cleaning apparatus 102, a first horizontal/vertical position conversion apparatus 108(1), a vertical type magnetron sputtering apparatus 10 (particularly a right chamber 18R), a first vertical/horizontal position conversion apparatus 110(1), and a multilayered organic layer vapor deposition apparatus 104 arranged in a row along one direction of the X-direction in order named. The layout is reversed as indicated by arrow 140 such that a Li vapor deposition apparatus 106, a second horizontal/vertical position conversion apparatus 108(2), the magnetron sputtering apparatus 10 (particularly a left chamber 18L), a second vertical/horizontal position conversion apparatus 110(2), . . . , and an unloader 116 are arranged in a row along a reverse direction of the X-direction in order named.

In this system, a substrate P having no ITO film is transported into the loader 100. An anode electrode 122 (ITO film) is formed on the substrate P with use of a pattern mask in the right chamber 18R of the magnetron sputtering apparatus 10. In this case, ITO is used as a base material of the right-side target 12R (FIG. 1).

Subsequently, the substrate P is converted from the vertical position into the horizontal position in the first vertical/horizontal position conversion apparatus 110(1). An organic layer having a multilayered structure is formed in the multilayered organic layer vapor deposition apparatus 104. Then, as shown by arrow 140, the substrate P is reversed in direction by a substrate inverter apparatus (not shown). An organic layer having a multilayered structure and a Li layer are sequentially formed on the substrate P in the Li vapor deposition apparatus 106. The substrate P is converted from the horizontal position into the vertical position by the second horizontal/vertical position conversion apparatus 108(2), and a Ag cathode electrode 128 is formed on the substrate P with use of a pattern mask in the left chamber 18L of the magnetron sputtering apparatus 10. In this case, Ag is used as a base material of the left-side target 12L (FIG. 1).

Thus, with one magnetron sputtering apparatus 10 in this system, a sputtering process for forming an ITO film and a sputtering process for forming a Ag cathode electrode can be performed on a substrate P in different steps or can be performed on different substrates P and P in parallel or simultaneously.

### Fourth Embodiment

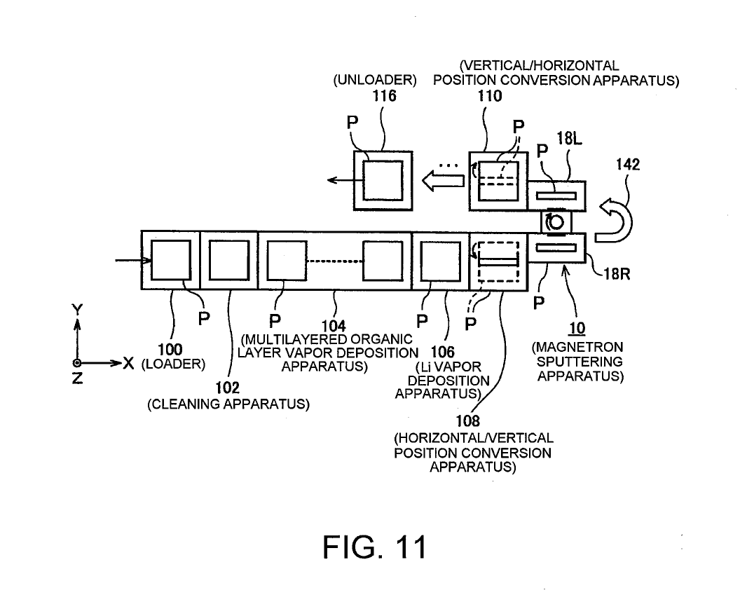

FIG. 11 shows another layout of the in-line system for manufacturing an organic EL display that includes a magnetron sputtering apparatus 10 according to the present embodiment.

In this system, a Ag film is formed as a cathode electrode 128 on a substrate P in the right chamber 18R of the vertical type magnetron sputtering apparatus 10. Subsequently, as shown by arrow 142, the substrate P is reversed in direction by a substrate inverter apparatus (not shown), and an Al film is then stacked and formed on the Ag film in the left chamber 18L of the magnetron sputtering apparatus 10. Thus, when a multilayered film of Ag and Al is formed in the separate sputtering deposition chambers (18R and 18L), layers of the multilayered film can be separated from each other more clearly as compared to a case where a stacking deposition is performed in one sputtering chamber.

### Fifth Embodiment

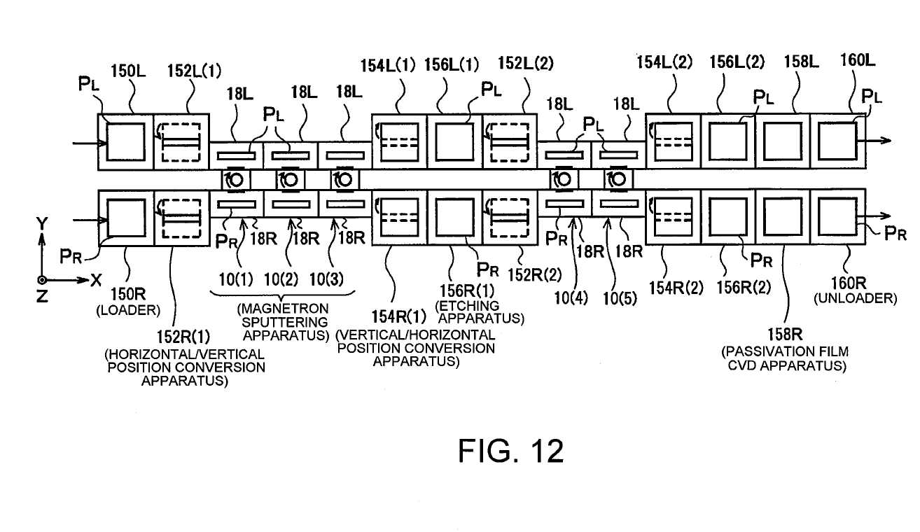

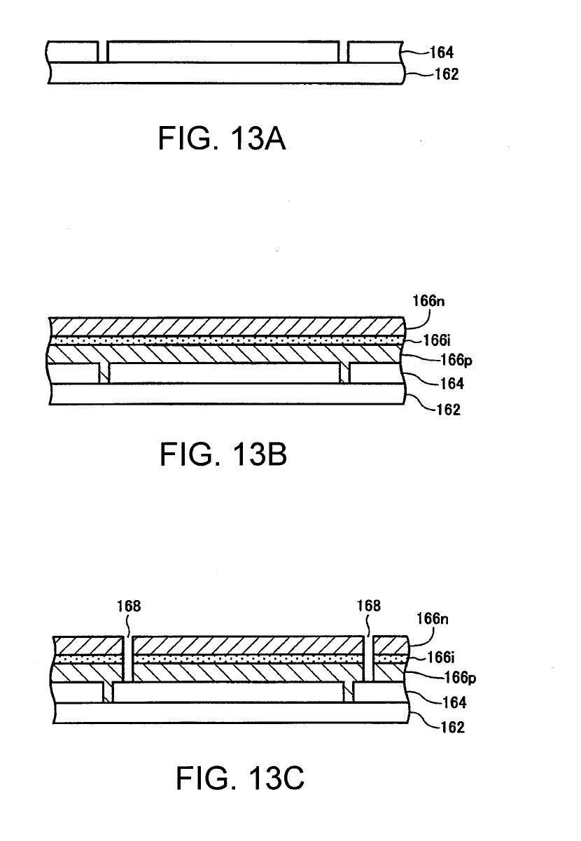

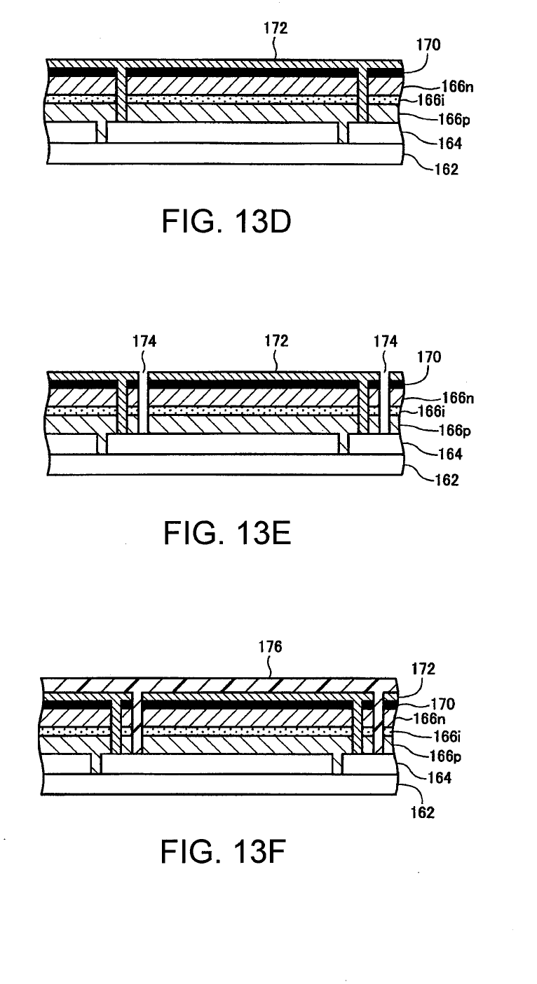

Next, an embodiment in which the magnetron sputtering apparatus 10 according to the present embodiment is applied to an in-line system for manufacturing a solar cell will be described with reference to FIGS. 12 and 13A to 13F.

As shown in FIG. 12, this in-line system includes a pair of loaders 150L and 150R, a pair of first horizontal/vertical position conversion apparatuses 152L(1) and 152R(1), first, second, and third vertical type magnetron sputtering apparatuses 10(1), 10(2), and 10(3), a pair of first vertical/horizontal position conversion apparatuses 154L(1) and 154R(1), a pair of first etching apparatuses 156L(1) and 156R(1), a pair of second horizontal/vertical position conversion apparatuses 152L(2) and 152R(2), fourth and fifth vertical type magnetron sputtering apparatuses 10(4) and 10(5), a pair of second vertical/horizontal position conversion apparatuses 154L (2) and 154R(2), a pair of second etching apparatuses 156L(2) and 156R(2), a pair of passivation film CVD apparatuses 158L and 158R, and a pair of unloaders 160L and 160R arranged in two rows of the left and right rows along one direction (X-direction) in order named.

Among the group of apparatuses in the aforementioned lines, all of the apparatuses from the first horizontal/vertical position conversion apparatuses 152L(1) and 152R(1) to the passivation film CVD apparatuses 158L and 158R are pressure-reducible apparatuses or pressure-reducible position conversion apparatuses.

In FIG. 12, P_{L} denotes a substrate subject to a series of processes in the left process line (150L-160L), whereas P_{R} denotes a substrate subject to a series of processes in the right process line (150R-160R).

A process of manufacturing a solar cell in this in-line system will be described with reference to FIGS. 13A to 13F.

First, the substrates P_{L} and P_{R} to be transported into the loaders 150L and 150R are formed of a transparent plate or sheet such as glass. As shown in FIG. 13A, a transparent conductive film 164 made of, for example, ZnO to which Ge has been added is preformed on a device formation surface of a glass substrate 162.

After the substrates P_{L} and P_{R} are transported to the loaders 150L and 150R in the horizontal position, they are converted from the horizontal position into the vertical position in the adjacent first horizontal/vertical position conversion apparatuses 152L(1) and 152R(1). Then the substrates P_{L} and P_{R} are subjected to a succession of sputtering deposition processes in the first, second, and third magnetron sputtering apparatuses 10(1), 10(2), and 10(3). As shown in FIG. 13B, a p-type amorphous silicon layer 166p is formed in the first magnetron sputtering apparatus 10(1), an intrinsic (i-type) amorphous silicon layer 166i is formed in the second magnetron sputtering apparatus 10(2), and an n-type amorphous silicon layer 166n is formed in the third magnetron sputtering apparatus 10(3). The pin-structure amorphous silicon layers (166p, 166i, and 166n) thus stacked constitute a power generation layer.

Next, the substrates P_{L} and P_{R} are converted from the vertical position to the horizontal position within the first vertical/horizontal position conversion apparatuses 154L(1) and 154R(1) and transported to the first etching apparatuses 156L(1) and 156R(1) in the horizontal position. The first etching apparatuses 156L(1) and 156R(1) define contact holes 168 in the power generation layer (166p, 166i, and 166n) by, for example, laser etching as shown in FIG. 13C.

Subsequently, the substrates P_{L} and P_{R} are converted from the horizontal position to the vertical position in the second horizontal/vertical position conversion apparatuses 152L(1) and 152R(1) and are subjected to a succession of sputtering deposition processes in the fourth and fifth magnetron sputtering apparatuses 10(4) and 10(5). As shown in FIG. 13D, a Mg film 170, which serves as a metal having a low work function, is formed in the fourth magnetron sputtering apparatus 10(4), and an Al electrode 172 is formed in the fifth magnetron sputtering apparatus 10(5). At that time, Al is embedded into the contact holes 168.

Thereafter, the substrates P_{L} and P_{R} are converted from the vertical position into the horizontal position in the second vertical/horizontal position conversion apparatuses 154L(2) and 154R(2) and transported to the second etching apparatuses 156L(2) and 156R(2) in the horizontal position. As shown in FIG. 13E, the second etching apparatuses 156L(2) and 156R(2) define grooves 174 for isolation and passivation that extend through the electrode layer (170 and 172) and the power generation layer (166p, 166i, and 166n) by, for example, laser etching.

Subsequently, the substrates P_{L} and P_{R} are transported to the second passivation film CVD apparatuses 114L(2) and 114R(2) in the horizontal position. As shown in FIG. 13F, in the second passivation film CVD apparatuses 114L(2) and 114R(2), an insulative protective film 176 made of, for example, silicon nitride (SiN) is formed so as to cover surfaces of the substrates P_{L} and P_{R}. At that time, the protective film 176 is also embedded in the grooves 174.

Thus, a series of processes in this in-line system is completed. The processed substrates P_{L} and P_{R} are taken out of the unloaders 160L and 160R into the outside under the atmospheric pressure.

As described above, in this in-line system for manufacturing a solar cell, five vertical type magnetron sputtering apparatuses 10(1)-10(5) are simultaneously operated in the two lines of left and right process lines. Each of the vertical type magnetron sputtering apparatuses 10(1)-10(5) has a performance equivalent to that of two magnetron sputtering apparatuses. (The overall vertical type magnetron sputtering apparatuses have a performance equivalent to that of 10 magnetron sputtering apparatuses.) Thus, the throughput is remarkably improved.

The above example relates to a single junction solar cell. Nevertheless, the present invention is applicable to a multi-junction (tandem) solar cell.

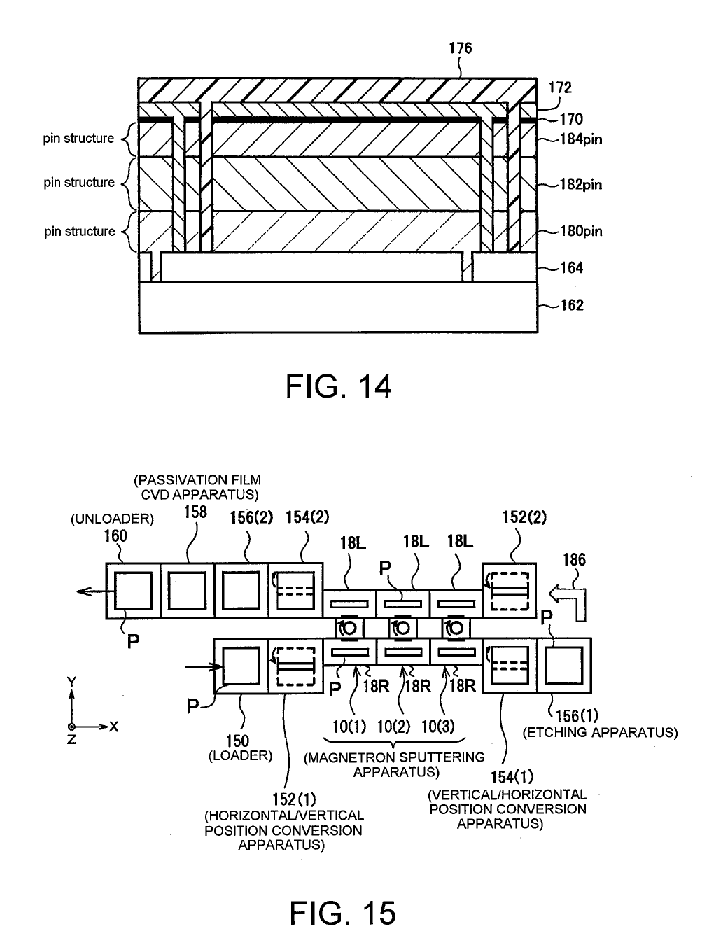

For example, in a power generation layer of a tandem solar cell shown in FIG. 14, an amorphous silicon layer 180pin, a microcrystalline silicon germanium layer 182pin, and a microcrystalline germanium layer 184pin having a pin-structure are stacked in order named from the lower layer. The solar cell is formed of a semiconductor thin film having nine layers in total. Those three pin junctions 180pin, 182pin, and 184pin have different forbidden bandwidths or light absorption spectra. Thus, the energy of solar rays can be converted into electric power with less waste.

In this case, when the in-line system has the same layout as FIG. 12, nine vertical type magnetron sputtering apparatuses 10(1)-10(9) may be arranged in series in order to form a power generation layer having a nine-layer structure. The magnetron sputtering apparatuses may be operated simultaneously in the two lines of the left and right process lines. As with the above example, two vertical type magnetron sputtering apparatuses 10(10)-10(11) may be arranged in series in order to form an upper electrode layer (170 and 172) having a two-layer structure. The magnetron sputtering apparatuses may be operated simultaneously in the two lines of the left and right process lines. Therefore, the eleven vertical type magnetron sputtering apparatuses 10(1)-10(11) have a performance equivalent to that of 22 magnetron sputtering apparatuses as a whole. Thus, the throughput is remarkably improved over the case of a single junction solar cell.

### Sixth Embodiment

FIG. 15 shows a modification of the in-line system for manufacturing a single junction solar cell (FIG. 12).

This in-line system includes a loader 150, a first horizontal/vertical position conversion apparatus 152(1), first, second, and third vertical type magnetron sputtering apparatuses 10(1), 10(2), and 10(3) (particularly the right chamber 18R of each apparatus), a first vertical/horizontal position conversion apparatus 154(1), and a first etching apparatus 156(1) arranged in a row along one direction of the X-direction in order named. The layout is reversed as indicated by arrow 186 such that a second vertical/horizontal position conversion apparatus 154(2), the first, second, and third magnetron sputtering apparatuses 10(1), 10(2), and 10(3) (particularly the left chamber 18L of each apparatus), a second etching apparatus 156(2), a passivation film CVD apparatus 158, and an unloader 160 are arranged in a row along a reverse direction of the X-direction in order named.

In the first process line, a p-type amorphous silicon layer 166p, an intrinsic (i-type) amorphous silicon layer 166i, and an n-type amorphous silicon layer 166n are respectively formed in the right chambers 18R of the first, second, and third magnetron sputtering apparatuses 10(1), 10(2), and 10(3) to form a single power generation layer.

In the second process line, a Mg film 170 of a metal having a low work function is formed in the left chamber 18L of the third magnetron sputtering apparatus 10(3), and Al electrodes 172 are formed in the left chambers 18L and 18L of the second and first magnetron sputtering apparatuses 10(2) and 10(1).

In a case where the film thickness of one layer to be formed by the magnetron sputtering apparatus 10 is relatively large so that a relatively long period of time is required for formation of a thin film, the tact time of one apparatus can be shortened by employing a multi-unit structure of this embodiment or a multi-unit structure of a series connection as shown in FIG. 6.

### Seventh Embodiment

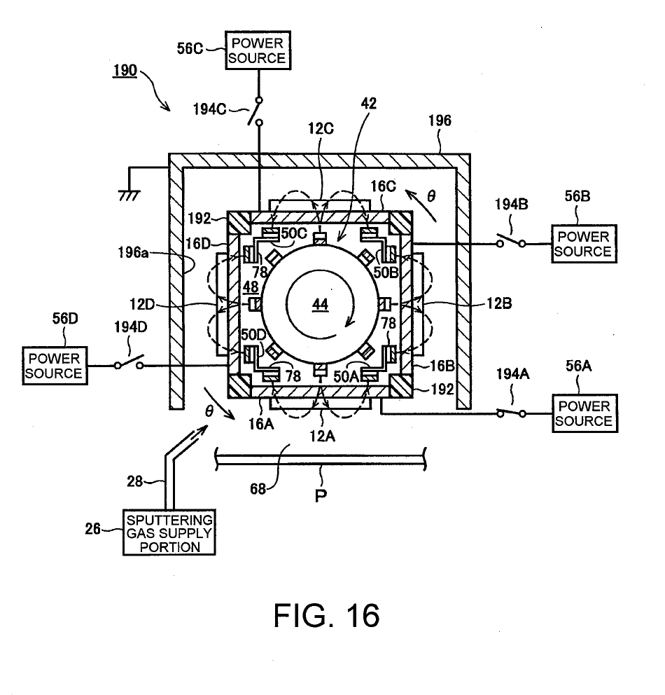

FIG. 16 shows a configuration of a magnetron sputtering apparatus 190 according to another embodiment.

This magnetron sputtering apparatus 190 has a configuration in which a plurality of targets, for example, four targets 12A, 12B, 12C, and 12D are assembled on an integral polyhedron (tetrahedron) so as to surround a magnetic field generation mechanism 42. This target assembly can perform an index transportation in a circumferential direction (e) around a columnar rotation axis 44 of the magnetic field generation mechanism 42.

In this magnetron sputtering apparatus 190, any one of the four targets 12A, 12B, 12C, and 12D can be selected, exposed to a sputtering process space 68 (opposed to a substrate P), and subjected to a sputtering deposition. The selected target can be switched to another target by the index transportation. Therefore, the magnetron sputtering apparatus 190 can be used such that, for example, the target 12A of Al is first selected as an operating target so as to form an Al layer on one substrate P and switched to the target 12B of Ti by the index transportation so as to stack a Ti layer on the Al layer. Thus, by switching an operating target with the index transportation, a sputtering deposition can successively be performed to form thin films of different materials or the same material.

The targets 12A, 12B, 12C, and 12D are respectively coupled to backing plates 16A, 16B, 16C, and 16D connected via dielectric frame members 192. Individual power sources (power supply mechanisms) 56A, 56B, 56C, and 56D are electrically connected to the backing plates 16A, 16B, 16C, and 16D via switches 194A, 194B, 194C, and 194D.

For example, a housing 196 is made of aluminum. A surface of the housing 196 that faces the sputtering process space 68 (the lower surface in the drawing) has an opening. The housing 196 is electrically grounded. The interior of the housing 196 and the sputtering process space 68 are maintained in a decompressed state and supplied with a sputtering gas (e.g., Ar gas) from a sputtering gas supply portion 26.

For a usual use, for example, when the target 12A is selected as an operating target, only the switch 194A is turned on during a sputtering process, whereas the other switches 194B, 194C, and 194D are all turned off. No electric power is supplied to non-operating targets of the targets 12B, 12C, and 12D.

However, one of ways to use the apparatus includes supplying electric power to one of non-operating targets of the targets 12B, 12C, and 12D to perform dummy sputtering toward an inner wall 196a of the housing 196. For example, when a surface of a new target that has just been replaced is oxidized, an oxide film of the target can be removed by dummy sputtering. After this cleaning, the apparatus may be used for a regular sputtering deposition process.

Thus, the interior of the housing 196 can be used for a dummy sputtering space. The inner wall 196a of the housing 196 may have such a moderately rough surface that a film is prevented from being attached and removed by dummy sputtering. Alternatively, an attachment prevention plate (not shown) may detachably be provided on the inner wall 196a of the housing 196.

During the sputtering deposition process, the substrate P may be of a fixed type in which the substrate P rests within the sputtering process space 68. Alternatively, the substrate P may be of a scanning type in which the substrate P is moved across the sputtering process space 68.

### Other Embodiments

Although preferred embodiments have been described, the present invention is not limited to the above embodiments. Various modifications can be made therein without departing from the technical concept of the present invention.

For example, the magnetron sputtering apparatus in the above embodiments is of a vertical type that performs a sputtering process on a substrate that is raised in the vertical direction. However, the magnetron sputtering apparatus may be of a horizontal type that performs a sputtering process on a substrate that is in another position, e.g., a substrate that is laid in the horizontal direction.

Furthermore, a mechanism for maintaining a constant distance between the target and the magnetic field generation mechanism (particularly the rotation magnet) (for example, a mechanism for moving the target holding mechanisms independently of each other) may be provided so as to maintain a constant magnetic field strength on a surface of the target irrespective of erosion state of the target.

### DESCRIPTION OF REFERENCE NUMERALS

10 magnetron sputtering apparatus
12L, 12R target
14 sputtering gun unit
16L, 16R backing plate
18L, 18R chamber
20L, 20R processing chamber
22L, 22R substrate transport path
24L, 24R vertically-oriented tray
26L, 26R sputtering gas supply portion
32L, 32R gas-discharging device
42 magnetic field generation mechanism
44 columnar rotation axis
46 plate magnet
48 rotation magnet group
50L, 50R fixing peripheral magnet
52L, 52R magnetic cover
54L, 54R feeder member
56 power supply mechanism
58L, 58R high-frequency power source
64L, 64R DC power source
68L, 68R sputtering space
190 magnetron sputtering apparatus
12A, 12B, 12C, 12D target
16A, 16B, 16C, 16D backing plate

1. A magnetron sputtering apparatus comprising:
a magnetic field generation mechanism including a rotation magnet group of a plurality of plate magnets attached to an outer circumferential surface of a columnar rotation axis in a predetermined arrangement pattern, the magnetic field generation mechanism being operable to drive rotation of the rotation magnet group integrally with the columnar rotation axis;
a plurality of target holding mechanisms each extending in parallel to the columnar rotation axis such that a rear face of each of the target holding mechanisms faces the rotation magnet group, the plurality of target holding mechanisms being provided around the rotation magnet group so that the target holding mechanisms do not overlap in a radial direction of the columnar rotation axis;
a plurality of processing chambers that receive substrates to be processed in a state in which the substrates are opposed to front faces of the plurality of target holding mechanisms so that the substrates can individually be transported into and from the plurality of processing chambers, the plurality of processing chambers being capable of decompression;
a gas supply mechanism for supplying a sputtering gas to the processing chambers; and
a power supply mechanism for supplying electric power for electric discharge to each of the targets to generate plasma of the sputtering gas in each of the processing chambers,
wherein a magnetic field for confining the plasma of the sputtering gas is formed by the magnetic field generation mechanism so that a sputtering process can be performed in the plurality of processing chambers.

2. The magnetron sputtering apparatus as recited in claim 1, wherein the target holding mechanisms provided around the columnar rotation axis include two target holding mechanisms arranged in parallel to each other so that the columnar rotation axis is located between the two target holding mechanisms.

3. The magnetron sputtering apparatus as recited in claim 1, wherein the magnetic field generation mechanism forms a circular or elliptic plasma ring extending in a direction crossing an axial direction of the columnar rotation axis on a front face of each of targets held by the plurality of target holding mechanisms, and the plasma ring is moved in parallel to the axial direction of the columnar rotation axis by rotating the rotation magnet group.

4. The magnetron sputtering apparatus as recited in claim 1, wherein the magnetic field generation mechanism includes a plurality of fixing peripheral magnetic shells or ferromagnetic members arranged so as to surround the rotation magnet group.

5. The magnetron sputtering apparatus as recited in claim 4, wherein the plate magnets of the rotation magnet group have a surface magnetized into one of an N-pole and an S-pole, and are attached to the columnar rotation axis in an arrangement pattern in which they are wound on the outer circumferential surface of the columnar rotation axis while they are translated in the form of a belt along with another plate magnet or ferromagnetic member having a surface magnetized into the other pole of the N-pole and the S-pole.

6. The magnetron sputtering apparatus as recited in claim 4, wherein the plate magnets of the rotation magnet group are magnetized in a thickness direction and are attached to the columnar rotation axis in an arrangement pattern in which one or more magnetic pole rings in which N-poles and S-poles are wound in a form of a belt so as to make a round of the columnar rotation axis or form a spiral on the outer circumferential surface of the columnar rotation axis with varying positions in an axial direction of the columnar rotation axis are formed at predetermined intervals in the axial direction of the columnar rotation axis, and
the fixing peripheral magnetic shells are magnetized in a thickness direction and arranged so that one of an N-pole and an S-pole of the fixing peripheral magnetic shells is opposed to the target holding mechanisms.

7. The magnetron sputtering apparatus as recited in claim 1, wherein the power supply mechanism has a plurality of DC power sources electrically connected to the plurality of target holding mechanisms individually.

8. The magnetron sputtering apparatus as recited in claim 1, wherein the power supply mechanism has a plurality of high-frequency power sources electrically connected to the plurality of target holding mechanisms individually.

9. The magnetron sputtering apparatus as recited in claim 8, comprising a conductive cover, electrically grounded, for individually covering high-frequency feeder portions on a rear side of the plurality of target holding mechanisms in order to isolate high frequencies provided to the plurality of target holding mechanisms by the power supply mechanism from each other.

10. The magnetron sputtering apparatus as recited in claim 1, wherein the plurality of target holding mechanisms have a plurality of conductive backing plates for supporting a target at a rear side of the target, and each of the targets is electrically connected to the power supply mechanism via a corresponding backing plate.

11. The magnetron sputtering apparatus as recited in claim 1, comprising a conductive cover for individually covering magnetic field spaces on a rear side of the plurality of target holding mechanisms in order to isolate magnetic fields provided to the plurality of target holding mechanisms by the magnetic field generation mechanism from each other.

12. The magnetron sputtering apparatus as recited in claim 1, comprising a substrate movement mechanism for moving the substrate in a direction that is in parallel to the target holding mechanism and crosses an axial direction of the columnar rotation axis so that the substrate moves across a sputtering space provided in front of the target holding mechanism within each of the processing chambers.

13. The magnetron sputtering apparatus as recited in claim 12, wherein components of the apparatus are arranged so that the substrate movement mechanism moves the substrate in a state in which the substrate is substantially in parallel to a direction of gravity.

14. The magnetron sputtering apparatus as recited in claim 13, wherein components of the apparatus are arranged so that the axial direction of the columnar rotation axis substantially accords with the direction of gravity.

15. The magnetron sputtering apparatus as recited in claim 1, wherein a transport chamber for transporting the substrate under a reduced pressure is provided between the plurality of processing chambers, the substrate is transported between the plurality of processing chambers via the transport chamber, and a deposition process is continuously performed in an in-line manner on the substrate in each of the processing chambers.

16. A magnetron sputtering apparatus comprising:
a first magnetic field generation mechanism including a first rotation magnet group of a plurality of plate magnets attached to an outer circumferential surface of a first columnar rotation axis in a predetermined arrangement pattern, the first magnetic field generation mechanism being operable to drive rotation of the first rotation magnet group integrally with the first columnar rotation axis;
a first target holding mechanism extending in parallel to the first columnar rotation axis such that a rear face of the first target holding mechanism faces the first rotation magnet group, the first target holding mechanism being provided on one side of the first rotation magnet group;
a second target holding mechanism extending in parallel to the first columnar rotation axis such that a rear face of the second target holding mechanism faces the first rotation magnet group, the second target holding mechanism being provided on an opposite side of the first rotation magnet group so that the second target holding mechanism is opposed in parallel to the first target holding mechanism;
a second magnetic field generation mechanism including a second rotation magnet group of a plurality of plate magnets attached to an outer circumferential surface of a second columnar rotation axis extending in parallel to the first columnar rotation axis at a position spaced from the first columnar rotation axis in a predetermined arrangement pattern, the second magnetic field generation mechanism being operable to drive rotation of the second rotation magnet group integrally with the second columnar rotation axis;
a third target holding mechanism extending in parallel to the second columnar rotation axis such that a rear face of the third target holding mechanism faces the second rotation magnet group, the third target holding mechanism being substantially flush with the first target holding mechanism and being provided on one side of the second rotation magnet group;
a fourth target holding mechanism extending in parallel to the second columnar rotation axis such that a rear face of the fourth target holding mechanism faces the second rotation magnet group, the fourth target holding mechanism being opposed in parallel to the third target holding mechanism, being substantially flush with the second target holding mechanism, and being provided on an opposite side of the second rotation magnet group;
first, second, third, and fourth processing chambers that receive substrates to be processed in a state in which the substrates are opposed to front faces of the first, second, third, and fourth target holding mechanisms so that the substrates can be transported into and from the processing chambers, the processing chambers being capable of decompression;
a gas supply mechanism for supplying a sputtering gas to the first, second, third, and fourth processing chambers; and
a power supply mechanism for supplying electric power for electric discharge to the first, second, third, and fourth target holding mechanisms to generate plasma of the sputtering gas in the first, second, third, and fourth processing chambers,
wherein a magnetic field for confining the plasma of the sputtering gas is formed for the first and second target holding mechanisms by the first magnetic field generation mechanism so that a sputtering process can be performed in the first and second processing chambers, and
a magnetic field for confining the plasma of the sputtering gas is formed for the third and fourth target holding mechanisms by the second magnetic field generation mechanism so that a sputtering process can be performed in the third and fourth processing chambers.

17. The magnetron sputtering apparatus as recited in claim 16, comprising:
a first substrate movement mechanism for moving a first substrate to be processed in a direction that is in parallel to the first and third target holding mechanisms and is perpendicular to axial directions of the first and second columnar rotation axis so that the first substrate moves sequentially across the first and third sputtering spaces respectively provided in front of the first and third target holding mechanisms within the first and third processing chambers; and
a second substrate movement mechanism for moving a second substrate to be processed in a direction that is in parallel to the second and fourth target holding mechanisms and is perpendicular to the axial directions of the first and second columnar rotation axis so that the second substrate moves sequentially across the second and fourth sputtering spaces respectively provided in front of the second and fourth target holding mechanisms within the second and fourth processing chambers.

18. A magnetron sputtering apparatus comprising:
a magnetic field generation mechanism including a rotation magnet group of a plurality of magnetic shells attached to an outer circumferential surface of a columnar rotation axis in a predetermined arrangement pattern, the magnetic field generation mechanism being operable to drive rotation of the rotation magnet group integrally with the columnar rotation axis;
a plurality of target holding mechanisms each extending in parallel to the columnar rotation axis such that a rear face of each of the target holding mechanisms faces the rotation magnet group, the plurality of target holding mechanisms being provided around the rotation magnet group so that the target holding mechanisms do not overlap in a radial direction of the columnar rotation axis;
a processing chamber that collectively receives the plurality of target holding mechanisms and receives a substrate to be processed so that the substrate can be transported into and from the processing chamber, the processing chamber being capable of decompression;
an index transportation mechanism for integrally moving the plurality of target holding mechanisms around the columnar rotation axis in a circumferential direction in order to align any one of the plurality of target holding mechanisms, as an operating target holding mechanism, with a predetermined operational position opposed to a regular sputtering space defined in the processing chamber;
a gas supply mechanism for supplying a sputtering gas to the processing chamber; and
a power supply mechanism for supplying electric power for electric discharge to the operating target holding mechanism in the processing chamber to discharge in the sputtering gas within the regular sputtering space,
wherein a magnetic field for confining plasma of the sputtering gas is formed for the operating target holding mechanism by the magnetic field generation mechanism so that a sputtering process can be performed in the regular sputtering space.

19. The magnetron sputtering apparatus as recited in claim 18, wherein a dummy sputtering space is provided in the processing chamber at a position opposed to one or more target holding mechanisms of the plurality of target holding mechanisms other than the operating target holding mechanism,
the power supply mechanism supplies electric power for electric discharge to a non-operating target holding mechanism to discharge in the sputtering gas within the dummy sputtering space, and
a magnetic field for confining plasma of the sputtering gas is formed for the non-operating target holding mechanism by the magnetic field generation mechanism so that a dummy sputtering process can be performed in the dummy sputtering space.

20. The magnetron sputtering apparatus as recited in claim 19, comprising a dummy sputtering attachment prevention portion for receiving and depositing sputtering particles emitted from a target held by the non-operating target holding mechanism to the dummy sputtering space.
